(19) United States
(12) Patent Application Publication
(10) Pub. No.: US 2025/0221129 A1
(43) Pub. Date: Jul. 3, 2025

(54) DISPLAY DEVICE

(71) Applicant: LG Display Co., Ltd., Seoul (KR)

(72) Inventors: Kyeong Min YUK, Paju-si (KR); Hyun Seok NA, Paju-si (KR); Joon Min JANG, Paju-si (KR); Seung Kyu IM, Paju-si (KR); Yong Hoon LEE, Paju-si (KR); Woo Sung KIM, Paju-si (KR); Jong Soo HAN, Paju-si (KR); Sang Hak SHIN, Paju-si (KR); Hyoung Sun PARK, Paju-si (KR); Hyun Chyol SHIN, Paju-si (KR); Seong Soo CHO, Paju-si (KR); Bong Soo JEON, Paju-si (KR)

(73) Assignee: LG Display Co., Ltd., Seoul (KR)

(21) Appl. No.: 18/979,333

(22) Filed: Dec. 12, 2024

(30) Foreign Application Priority Data
Dec. 27, 2023 (KR) 10-2023-0192374

(51) Int. Cl. H10H 29/41; H10H 29/37

(52) U.S. Cl. CPC H10H 29/41; H10H 29/37

(57) ABSTRACT

A display device can include a substrate having a display region, a non-display region and a bending region, an adhesive layer disposed on the substrate, a pixel driving circuit disposed on the adhesive layer in the display region, a buffer layer disposed on the adhesive layer and configured to cover the pixel driving circuit, a second protective pattern disposed in the non-display region to surround the display region, a first inorganic film disposed on the pixel driving circuit, and a second inorganic film disposed on the second protective pattern in the display region and the non-display region. The first inorganic film and the second inorganic film overlap in a region overlapping the second protective pattern.

### CROSS-REFERENCE TO RELATED APPLICATION

This application claims priority to Korean Patent Application No. 10-2023-0192374, filed in the Republic of Korea on Dec. 27, 2023, the entire contents of which is hereby expressly incorporated by reference into the present application.

### BACKGROUND

### 1. Field

The embodiments of the present disclosure relate to a display device using an inorganic light-emitting diode as a light source.

### 2. Discussion of the Related Art

An electroluminescent display device includes an organic light-emitting display device in which an organic light-emitting diode (OLED) is disposed and an inorganic light-emitting display device (hereinafter, referred to as “an LED display device”) in which an inorganic light-emitting diode (hereinafter, referred to as “an LED”) is disposed.

The electroluminescent display device displays images using self-luminous elements, and thus does not require a separate light source, for example, a backlight unit, and can be implemented in thin and various forms.

In the organic light-emitting display device, since an oxidation phenomenon between an organic light-emitting layer and an electrode can occur due to penetration of moisture and oxygen, a design for preventing penetration of oxygen and moisture is needed.

Recently, as an example of the inorganic light-emitting display device, a micro LED display device in which micro LEDs are disposed in pixels has been attracting attention as a next-generation display device. The micro LED can be an inorganic LED with a size of 100 μm or less. Micro LEDs are manufactured through a separate semiconductor process and transferred to pixel positions on a display panel substrate of the display device, and can be respectively disposed in sub-pixels for each color.

### SUMMARY OF THE DISCLOSURE

Since an insulating layer and an optical layer are made of organic materials, it can be difficult to prevent foreign substances such as moisture, hydrogen, and the like which are present outside a display panel from penetrating into the display panel, which can result in driving defects in a pixel driving circuit, a metal line, and the like. Further, when the insulating layer or optical layer is disposed on the display panel, a defect in which the insulating layer and the optical layer disposed in a non-display region flow out of the display panel can occur.

According to aspects of the present disclosure, as a first protective pattern, a second protective pattern, a first inorganic film, and a second inorganic film are disposed to prevent or delay the entry of foreign substances such as moisture, hydrogen, and the like penetrating from the outside, a defect such as corrosion or damage to a metal line and the like in the display panel can be prevented. Further, as an outer optical layer and an outer bank pattern are disposed, thicknesses of a second optical layer and the second inorganic film disposed in the non-display region can have values the same as or similar to a thickness of that in the display region, and a defect in which organic layers such as the second optical layer and the like flow out of the non-display region of the display panel due to process problems can be prevented.

The technical problems to be solved by the present disclosure are not limited to the above-mentioned technical problems, and other technical problems which are not mentioned will be clearly understood by those skilled in the art from the following description.

A display device according to some aspects of the present disclosure can include a substrate including a display region, a non-display region, and a bending region; an adhesive layer disposed on the substrate; a pixel driving circuit disposed on the adhesive layer in the display region; a buffer layer disposed on the adhesive layer and configured to cover the pixel driving circuit; a second protective pattern disposed in the non-display region to surround the display region; a first inorganic film disposed on the pixel driving circuit; and a second inorganic film disposed on the second protective pattern in the display region and the non-display region, wherein the first inorganic film and the second inorganic film overlap in a region overlapping the second protective pattern.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a view illustrating a display device according to one or more embodiments of the present disclosure;

FIG. 2 is an enlarged view illustrating region A in FIG. 1;

FIG. 3 is a view illustrating a partial region of a pixel;

FIG. 4 is a cross-sectional view taken along line I-I′ in FIG. 3;

FIG. 5 is a cross-sectional view taken along line II-II′ in FIG. 3;

FIG. 6 is a cross-sectional view taken along line III-III′ in FIG. 3;

FIG. 7 is a cross-sectional view illustrating an example in which a main light-emitting element and a sub light-emitting element are electrically connected to a pixel driving circuit;

FIG. 8 is a view illustrating a display device according to another embodiment of the present disclosure;

FIG. 9 is a cross-sectional view taken along line IV-IV′ in FIG. 8;

FIG. 10A is a view illustrating a display device according to another embodiment of the present disclosure;

FIG. 10B is an enlarged view of region B in FIG. 10A;

FIG. 11A is a cross-sectional view taken along line Y-Y′ in FIG. 10B;

FIG. 11B is a cross-sectional view taken along line Y-Y′ of the display device according to another embodiment of the present disclosure in FIG. 10B;

FIG. 11C is a cross-sectional view taken along line Y-Y′ of a display device according to still another embodiment of the present disclosure in FIG. 10B;

FIG. 12A is a cross-sectional view taken along line Z-Z′ in FIG. 10A;

FIG. 12B is a cross-sectional view taken along line Z-Z′ of the display device according to another embodiment of the present disclosure in FIG. 10A; and

FIG. 12C is a cross-sectional view taken along line Z-Z′ of the display device according to still another embodiment of the present disclosure in FIG. 10A.

### DETAILED DESCRIPTION OF THE EMBODIMENTS

Advantages and features of the present disclosure, and methods of achieving them will become apparent with reference to the following embodiments, which are described in detail, in conjunction with the accompanying drawings. The present disclosure is not limited to the embodiments to be described below and can be implemented in various different forms, the embodiments are only provided to completely disclose the present disclosure and completely convey the scope of the present disclosure to those skilled in the art, and the present disclosure is defined only by the scope of the claims.

Since the shapes, sizes, proportions, angles, numbers, and the like disclosed in the drawings for describing the embodiments of the present disclosure are only exemplary, the present disclosure is not limited to the items shown in the drawings. Throughout the disclosure, the same reference numerals refer to substantially the same components. Further, in describing the present disclosure, when it is determined that a detailed description of related known technology can unnecessarily obscure the gist of the present disclosure, the detailed description thereof will be omitted.

When ‘providing,’ ‘including,’ ‘having,’ ‘consisting of,’ and the like mentioned in the present disclosure are used, other parts can be added unless ‘only’ is used. A component expressed in a singular form can also be interpreted as a plural form unless explicitly stated otherwise.

In interpreting the components, it should be understood that an error range is included even when there is no separate explicit description.

When a positional relationship and an interconnection relationship between two components such as ‘on,’ ‘at an upper portion,’ ‘at a lower portion,’ ‘next to,’ ‘connect or couple,’ ‘crossing or intersecting,’ or the like are described, one or more other components can be interposed between the components unless there is a mention such as ‘immediately’ or ‘directly.’

When a temporal relationship is described as ‘after,’ in succession to,’ ‘and then,’ ‘before,’ or the like, the temporal relationship may not be continuous on a time axis unless ‘immediately’ or ‘directly’ is used.

First, second, and the like can be used in front of the names of components to distinguish the components, but functions or structures are not limited by these ordinal numbers or component names. For convenience of description, the ordinal numbers in front of the name of the same components can be different between embodiments.

The following embodiments can be partially or fully combined with each other, and technically, various types of interconnections and driving are possible. The embodiments can be implemented independently of each other or can be implemented together in a related relationship. Further, the term “can” fully encompasses all the meanings and coverages of the term “may.”

Hereinafter, various embodiments of the present disclosure will be described in detail with reference to the accompanying drawings. All the components of each display device/apparatus according to all embodiments of the present disclosure are operatively coupled and configured.

A display device according to one or more embodiments of the present disclosure includes a display region where an image is displayed or a display panel on which a screen is disposed and a pixel driving circuit which drives pixels of the display panel. The display region includes a pixel region where the pixels are disposed. The pixel region includes a plurality of light-emitting regions. A light-emitting element is disposed in each of the light-emitting regions. The pixel driving circuit can be built into the display panel.

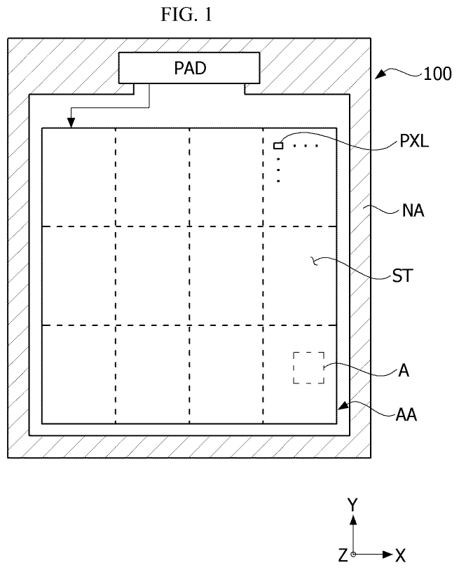

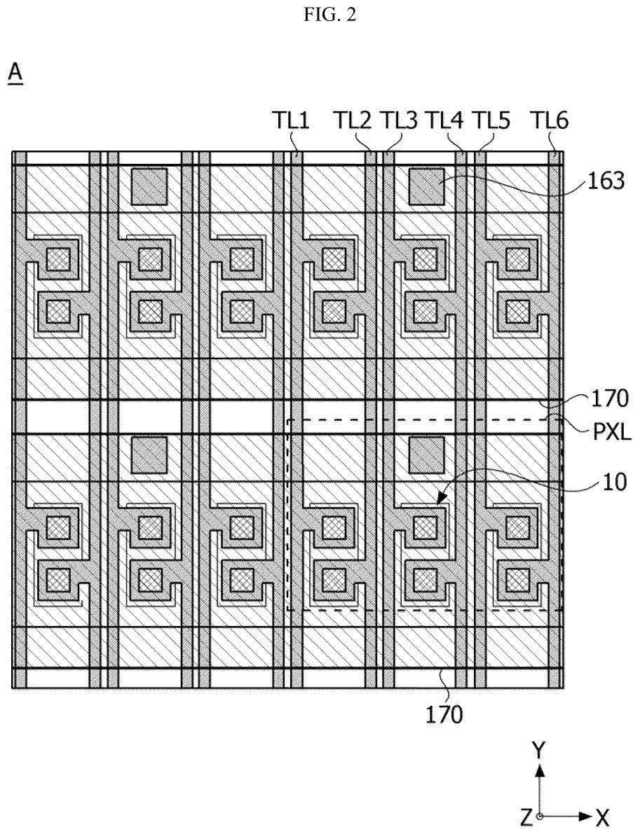

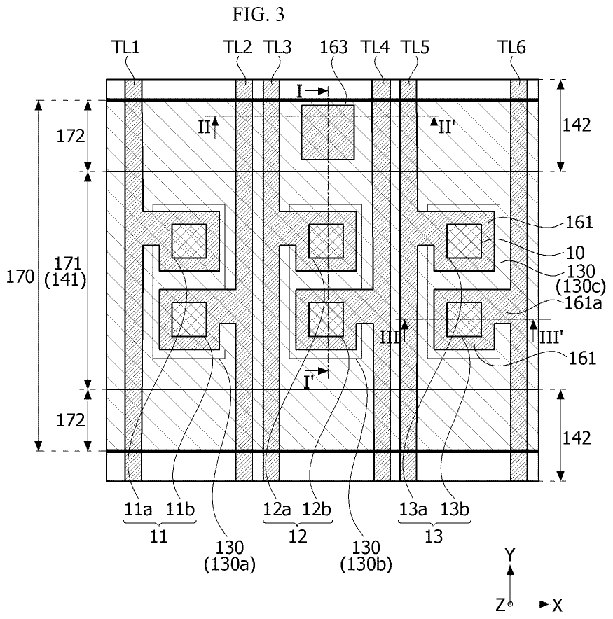

FIG. 1 is a view illustrating a display device according to one or more embodiments of the present disclosure. FIG. 2 is an enlarged view illustrating region A in FIG. 1. FIG. 3 is a view illustrating a partial region of a pixel.

Referring to FIGS. 1 and 2, a display device 100 according to one embodiment of the present disclosure includes a display panel where an input image is visually reproduced. The display panel can include a display region AA (or active area) where an image is displayed and a non-display region NA (or non-active area) where the image is not displayed. In the non-display region NA, various lines and driving circuits can be mounted, and a pad portion PAD to which an integrated circuit, a printed circuit, and the like are connected can be disposed. Here, the display panel can be a panel with a rectangular structure having a width in an X-axis direction, a length in a Y-axis direction, and a thickness in a Z-axis direction. In this case, the width and length of the display panel can be set to various design values according to application fields of the display device. The X-axis direction can mean a width direction, row direction, or lateral direction, the Y-axis direction can mean a length direction, column direction, or longitudinal direction, and the Z-axis direction can mean a vertical direction or thickness direction. Further, the X-axis direction, the Y-axis direction, and the Z-axis direction can be perpendicular to each other, but can also mean different directions not perpendicular to each other. Accordingly, each of the X-axis direction, the Y-axis direction, and the Z-axis direction can be described as one of a first direction, a second direction, and a third direction. Further, a surface extending in the X-axis direction and the Y-axis direction can mean a horizontal plane.

A plurality of light-emitting elements 10 disposed in the display region AA and forming pixels PXL can be micro-sized inorganic light-emitting elements. The inorganic light-emitting elements can be grown on a silicon wafer and then attached to the display panel through a transfer process.

The transfer process of the light-emitting elements 10 can be performed for each previously divided region. In FIG. 1, an example in which the display region AA is divided into twelve transfer regions ST is described, but the sizes or number of divided transfer regions are not limited thereto. The transfer process can be performed sequentially or simultaneously on a first transfer region ST to a twelfth transfer region ST. A blue light-emitting element 10, a green light-emitting element 10, and a red light-emitting element 10 can be sequentially transferred to each transfer region ST.

In the non-display region NA, data driving circuits or gate driving circuits can be disposed, and lines supplying control signals for controlling these driving circuits can be disposed. Here, the control signals can include various timing signals including clock signals, input data enable signals, and synchronization signals and can be received through the pad portion PAD.

The pixels PXL can be driven by the pixel driving circuit. The pixel driving circuit can receive a driving voltage, an image signal (digital signal), a synchronization signal synchronized with the image signal, and the like and output an anode voltage and a cathode voltage of the light-emitting element 10 to drive a plurality of pixels. The driving voltage can be a high-potential voltage EVDD. The cathode voltage can be a low-potential voltage EVSS applied to the pixels in common. The anode voltage can be a voltage corresponding to a pixel data value of the image signal. The pixel driving circuit can be disposed in the non-display region NA or under the display region AA.

Each pixel PXL can include a plurality of sub-pixels having different colors. For example, each of the plurality of pixels can include a red sub-pixel where the light-emitting element 10 which emits red wavelength light is disposed, a green sub-pixel where the light-emitting element 10 which emits green wavelength light is disposed, and a blue sub-pixel where the light-emitting element 10 which emits blue wavelength light is disposed. The plurality of pixels can further include a white pixel.

Referring to FIGS. 2 and 3, the plurality of pixels PXL can be continuously disposed in a first direction (an X-axis direction) and a second direction (a Y-axis direction). A plurality of sub-pixels of the same color can be disposed in the pixel of the display region AA. For example, each of the plurality of pixels can include a first red sub-pixel where a 1-1 light-emitting element 11a which emits red wavelength light is disposed, a second red sub-pixel where a 1-2 light-emitting element 11b which emits red wavelength light is disposed, a first green sub-pixel where a 2-1 light-emitting element 12a which emits green wavelength light is disposed, a second green sub-pixel where a 2-2 light-emitting element 12b which emits green wavelength light is disposed, a first blue sub-pixel where a 3-1 light-emitting element 13a which emits blue wavelength light is disposed, and a second blue sub-pixel where a 3-2 light-emitting element 13b which emits blue wavelength light is disposed. The 1-1 light-emitting element 11a, the 2-1 light-emitting element 12a, and the 3-1 light-emitting element 13a can be interpreted as main light-emitting elements. The 1-2 light-emitting element 11b, the 2-2 light-emitting element 12b, and the 3-2 light-emitting element 13b can be interpreted as sub light-emitting elements.

One sub-pixel can include one or more light-emitting elements, and thus the luminance of the sub-pixel can be adjusted by increasing the luminance of the other light-emitting elements when one light-emitting element becomes defective. However, the present disclosure is not necessarily limited thereto, and one sub-pixel can include only one light-emitting element.

A plurality of first electrodes 161 can be respectively disposed under the light-emitting elements 10 and can be selectively connected to a plurality of signal lines TL1 to TL6 through a connection portion 161a. A high-potential voltage can be applied to the pixel driving circuit through the signal lines TL1 to TL6. The signal lines TL1 to TL6 and the first electrodes 161 can be formed as an integrated electrode pattern during an electrode patterning process.

For example, a first signal line TL1 can be connected to an anode electrode of the first red sub-pixel, and a second signal line TL2 can be connected to an anode electrode of the second red sub-pixel. A third signal line TL3 can be connected to an anode electrode of the first green sub-pixel, and a fourth signal line TL4 can be connected to an anode electrode of the second green sub-pixel. A fifth signal line TL5 can be connected to an anode electrode of the first blue sub-pixel, and a sixth signal line TL6 can be connected to an anode electrode of the second blue sub-pixel. When one sub-pixel includes only one light-emitting element, the number of signal lines TL can be reduced by half.

A second electrode 170 can be a cathode electrode that is disposed in each row and applies a cathode voltage to the light-emitting elements 10 continuously disposed in the first direction (the X-axis direction). A plurality of second electrodes 170 can be disposed to be spaced apart from each other in the second direction (the Y-axis direction). The plurality of second electrodes 170 can be connected to the cathode voltage through a contact electrode 163. Each of the plurality of second electrodes 170 can be electrically connected to the contact electrode 163. However, the present disclosure is not necessarily limited thereto, and the second electrode 170 may not be divided into the plurality of second electrodes 170 and can be configured as one electrode layer and function as a common electrode.

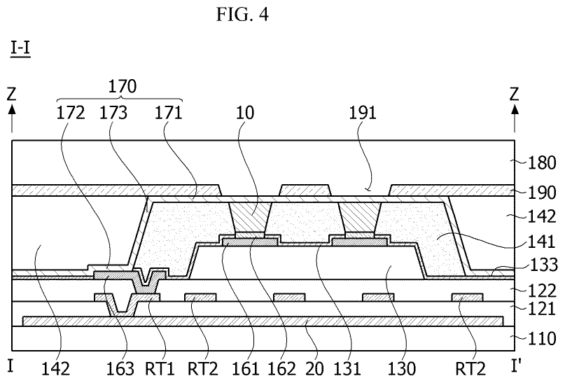

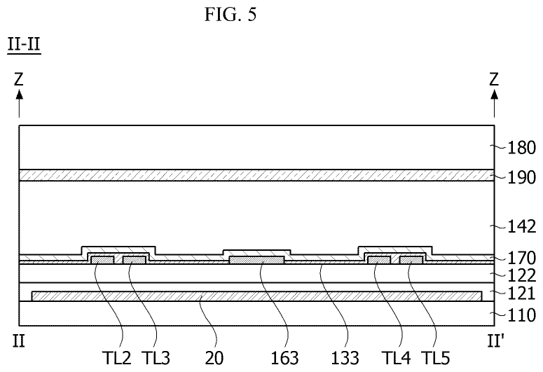

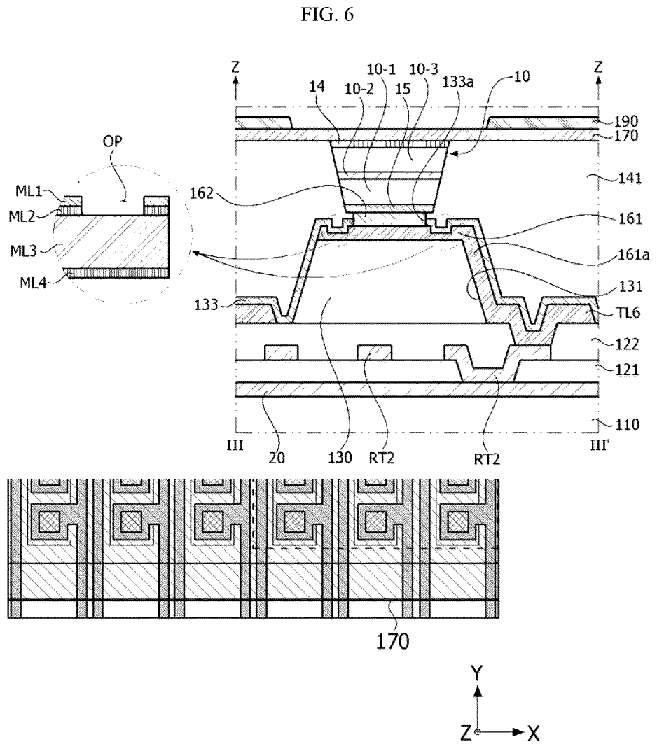

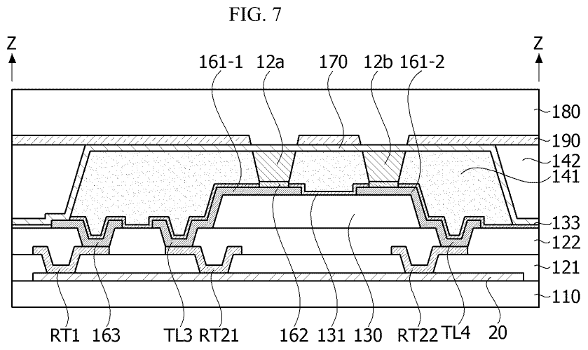

FIG. 4 is a cross-sectional view taken along line I-I′ in FIG. 3. FIG. 5 is a cross-sectional view taken along line II-II′ in FIG. 3. FIG. 6 is a cross-sectional view taken along line III-III′ in FIG. 3. FIG. 7 is a cross-sectional view illustrating an example in which two light-emitting elements are connected to the pixel driving circuit.

Referring to FIGS. 3 to 5, the display device according to the embodiment includes the plurality of first electrodes 161 and the contact electrode 163 disposed on a substrate 110, the plurality of light-emitting elements 10 disposed on the plurality of first electrodes 161, a first optical layer 141 disposed between the plurality of light-emitting elements 10, and the second electrode 170 disposed on the plurality of light-emitting elements 10.

The substrate 110 can be made of plastic having flexibility. For example, the substrate 110 can be manufactured as a single-layer or multi-layer substrate made of a material selected from polyimide, polyethylene terephthalate, polyethylene naphthalate, polycarbonate, polyethersulfone, polyarylate, polysulfone, and a cyclic-olefin copolymer, but is not limited thereto. For example, the substrate 110 can be a ceramic substrate or glass substrate.

A pixel driving circuit 20 can be disposed in the display region AA on the substrate 110. The pixel driving circuit 20 can include a plurality of thin film transistors using an amorphous silicon semiconductor, a polycrystalline silicon semiconductor, or an oxide semiconductor.

The pixel driving circuit 20 can include at least one driving thin film transistor, at least one switching thin film transistor, and at least one storage capacitor. The pixel driving circuit 20 can be formed on the substrate 110 through a thin film transistor (TFT) manufacturing process when including a plurality of thin film transistors. In the embodiment, the pixel driving circuit 20 can be a concept that collectively refers to a plurality of thin film transistors electrically connected to the light-emitting elements 10.

The pixel driving circuit 20 can be a driving driver manufactured on a single crystal semiconductor substrate 110 using a metal-oxide-silicon field effect transistor (MOSFET) manufacturing process. The driving driver can include a plurality of pixel driving circuits to drive a plurality of sub-pixels. When the pixel driving circuit 20 is implemented as a driving driver, after an adhesive layer is disposed on the substrate 110, the driving driver can be mounted on the adhesive layer through a transfer process.

A buffer layer 121 which covers the pixel driving circuit 20 can be disposed on the substrate 110. The buffer layer 121 can be made of an organic insulating material, for example, photosensitive photo acryl or photosensitive polyimide, but is not limited thereto.

The buffer layer 121 can be made by stacking an inorganic insulating material, for example, silicon nitride (SiNₓ), silicon oxide (SiO₂), or the like in a multi-layer manner, or by stacking an organic insulating material and an inorganic insulating material in a multi-layer manner.

An insulating layer 122 can be disposed on the buffer layer 121. The insulating layer 122 can be made of an organic insulating material, for example, photosensitive photo acryl or photosensitive polyimide, but is not limited thereto. Connection lines can be disposed on the buffer layer 121. The connection lines can include a plurality of connection lines such as a first connection line RT1, a second connection line RT2, and the like. The connection lines can be connected to the corresponding signal lines TL. The signal lines can include the first signal line TL1 to the sixth signal line TL6, but are not limited thereto. The connection lines can include a plurality of line patterns disposed on different layers with one or more insulating layers interposed therebetween. The line patterns disposed on different layers can be electrically connected through contact holes passing through the insulating layer.

A plurality of bank patterns 130 can be disposed on the insulating layer 122. At least one light-emitting element 10 can be disposed on each bank pattern 130. For example, a first light-emitting element 11 can be disposed on a first bank pattern 130a, a second light-emitting element 12 can be disposed on a second bank pattern 130b, and a third light-emitting element 13 can be disposed on a third bank pattern 130c.

The bank pattern 130 can be made of an organic insulating material, for example, photosensitive photo acryl or photosensitive polyimide, but is not limited thereto. The bank pattern 130 can guide a position where the light-emitting elements 10 will be attached during the transfer process of the light-emitting elements 10. The bank pattern 130 can also be omitted.

A solder pattern 162 can be disposed on the first electrode 161. The solder pattern 162 can be made of indium (In), tin (Sn), or an alloy thereof, but is not limited thereto.

Each of the plurality of light-emitting elements 10 can be mounted on the solder pattern 162. One pixel can include light-emitting elements 10 of three colors. The first light-emitting element 11 can be a red light-emitting element, the second light-emitting element 12 can be a green light-emitting element, and the third light-emitting element 13 can be a blue light-emitting element. Two light-emitting elements can be mounted in each sub-pixel.

The first optical layer 141 can cover the plurality of light-emitting elements 10 and the bank patterns 130. Accordingly, the first optical layer 141 can cover a space between the plurality of light-emitting elements 10 and a space between the plurality of bank patterns 130. The first optical layers 141 can be disposed to extend in the first direction (X) and spaced apart in the second direction (Y) to separate pixels spaced apart in the second direction. Accordingly, the first optical layers 141 can be separated between pixel rows. Here, a row can mean the first direction. Further, one pixel row formed of a plurality of pixels disposed in the first direction can be referred to as a pixel group. Accordingly, the display panel can include a plurality of pixel groups disposed to be spaced apart from each other in the second direction. For example, since the first optical layer 141 disposed in the first direction is disposed around the pixels, and the plurality of first optical layers 141 disposed corresponding to the plurality of pixel groups are disposed to be spaced apart from each other in the second direction, one first optical layer 141 disposed around the pixels forming one row can be separated from another first optical layer 141 disposed around the pixels forming another row.

The first optical layer 141 can include an organic insulating material in which fine metal particles such as titanium dioxide particles are dispersed. Light emitted from the plurality of light-emitting elements 10 can be scattered by the fine metal particles dispersed in the first optical layer 141 and emitted to the outside.

The second electrode 170 can be disposed on the plurality of light-emitting elements 10. The second electrode 170 can be connected to the plurality of pixels PXL in common. The second electrode 170 can be a thin electrode which transmits light. The second electrode 170 can be a transparent electrode material, for example, indium tin oxide (ITO), but is not necessarily limited thereto.

The second electrode 170 can extend in the first direction (the X-axis direction) and can be spaced apart in the second direction (the Y-axis direction). For example, one second electrode 170 can be formed to extend in the first direction, and a plurality of second electrodes 170 extending in the first direction can be spaced apart from each other in the second direction. In this case, the second electrodes 170 can be disposed corresponding to the pixels spaced apart from each other in the second direction, respectively. The second electrode 170 can include a first region 171 disposed on an upper surface of the light-emitting element 10 and an upper surface of the first optical layer 141, a second region 172 in contact with the contact electrode 163 and electrically connected to the contact electrode 163, and a third region 173 which is disposed on a side surface of the first optical layer 141 and connects the first region 171 and the second region 172.

Each of the plurality of second electrodes 170 can overlap the first optical layer 141 on a plane, and the third region 173 can cover an outer plane of the first optical layer 141.

A second optical layer 142 can be an organic insulating material surrounding the first optical layer 141. The second optical layer 142 can be disposed on the insulating layer 122 along with the first optical layer 141. The first optical layer 141 and the second optical layer 142 can include the same material (for example, a siloxane). For example, the first optical layer 141 can be a siloxane including titanium oxide (TiOx), and the second optical layer 142 can be a siloxane not including titanium oxide (TiOx). However, the present disclosure is not necessarily limited thereto, and the first optical layer 141 and the second optical layer 142 can be formed of the same material or can be formed of different materials.

According to the embodiment, since the second region 172 of the second electrode 170 is connected to the contact electrode 163 in an overall flat state, excessive stress is not concentrated at a point connected to the contact electrode 163. Accordingly, cracks in the second electrode 170 can be effectively prevented from occurring.

The second optical layer 142 can cover the second region 172 and the third region 173 of the second electrode 170. An upper surface of the second optical layer 142 and an upper surface of the first region 171 of the second electrode 170 can form the same plane. For example, the first region 171 and the second optical layer 142 can function as a planarization layer. Accordingly, since there is no step on a surface where a black matrix 190 is formed, a pattern of the black matrix 190 can be easily formed on the first optical layer 141 and the second optical layer 142. However, the present disclosure is not necessarily limited thereto, and the upper surfaces of the second optical layer 142 and the second electrode 170 can have different heights.

The black matrix 190 can be an organic insulating material to which a black pigment is added. The second electrode 170 can be in contact with the contact electrode 163 under the black matrix 190. Transmission holes 191 through which light emitted from the light-emitting elements 10 is emitted to the outside can be formed between the patterns of the black matrix 190. The transmission holes 191 can overlap the light-emitting elements 10 in the Z-axis direction, and a portion of the black matrix 190 can overlap the first optical layer 141 in the Z-axis direction. Here, the Z-axis direction can be referred to as the third direction. The black matrix 190 can improve the problem in which light from neighboring light-emitting elements 10 is mixed by the first optical layer 141 and then emitted.

A cover layer 180 can be an organic insulating material which covers the black matrix 190 and the second electrode 170. In FIGS. 2 and 3, the configurations of the black matrix 190 and the cover layer 180 are omitted.

The contact electrode 163 is electrically connected to the first connection line RT1 disposed at a lower portion, and the first connection line RT1 can be connected to the pixel driving circuit 20. Accordingly, the cathode voltage can be applied to the second electrode 170 through the contact electrode 163. The first electrode 161 can be electrically connected to the second connection line RT2. This will be described below.

Referring to FIG. 5, the contact electrode 163 and the signal lines TL1 to TL6 can be disposed on the same plane. The pixel driving circuit 20 can be disposed under the contact electrode 163 and the signal lines TL1 to TL6. When the pixel driving circuit 20 is a driving driver, a plurality of driving drivers can be disposed in the display panel.

A passivation layer 133 can expose the contact electrode 163 so that the contact electrode 163 and the second electrode 170 are electrically connected. Further, the passivation layer 133 can insulate the signal lines TL2 to TL5 and the second electrode 170. Here, the passivation layer 133 can be formed of an inorganic material.

Referring to FIG. 6, the connection portion 161a of the first electrode 161 can extend along one side surface 131 of the bank pattern 130 and can be electrically connected to the second connection line RT2 disposed on the insulating layer 122.

The first electrode 161, the connection portion 161a, the signal lines TL, and/or the connection lines RT1 and RT2 can include a single layer or multi-layer metal layer selected from titanium (Ti), molybdenum (Mo), and aluminum (Al).

The first electrode 161 or the signal lines TL can be formed to have a metal stack structure in which a plurality of metal layers are formed using metal materials having different materials, thicknesses, and the like. In this case, the first electrode 161, the connection portion 161a, and the signal lines TL can be formed simultaneously through the same manufacturing process. Here, the thickness can mean a width between one side and the other side of the metal layer disposed in the Z direction.

The first electrode 161 can include a first metal layer ML1 disposed under the solder pattern 162, a second metal layer ML2 disposed under the first metal layer ML1, a third metal layer ML3 disposed under the second metal layer ML2, and a fourth metal layer ML4 disposed under the third metal layer ML3. When the first electrode 161 is formed of the first metal layer ML1, the second metal layer ML2, the third metal layer ML3, and the fourth metal layer ML4, the first electrode 161 can be deposited in the order of the fourth metal layer ML4→the third metal layer ML3→the second metal layer ML2→the first metal layer ML1, and then patterned by performing a photolithography process and an etching process.

The first metal layer ML1 can be disposed in contact with a lower portion of the solder pattern 162 and electrically connected to the solder pattern 162.

Further, the first metal layer ML1 can include a transparent conductive oxide layer such as indium tin oxide (ITO) or indium zinc oxide (IZO) which has excellent adhesion and is corrosion and acid resistant. Here, the first metal layer ML1 can be referred to as an adhesive layer.

The second metal layer ML2 can be formed of a material having a different resistance value from the first metal layer ML1 and the third metal layer ML3. In this case, the second metal layer ML2 can be formed of a material having lower light reflectivity but a higher resistance value than the third metal layer ML3. For example, the second metal layer ML2 can include titanium (Ti) or molybdenum (Mo).

The third metal layer ML3 can be formed of a material having higher light reflectivity than the first metal layer ML1. In this case, the third metal layer ML3 can be formed of a material having higher light reflectivity than the second metal layer ML2. For example, the third metal layer ML3 can include aluminum (Al) or silver (Ag).

The light reflectivity of the third metal layer ML3 can be higher than the light reflectivity of each of the first metal layer ML1 and the second metal layer ML2.

The fourth metal layer ML4 can be formed of the same material as the second metal layer ML2. For example, the fourth metal layer ML4 can include titanium (Ti) or molybdenum (Mo).

After forming the first metal layer ML1, a reflective opening OP can be formed in the first electrode 161. The reflective opening OP can be a region where only a portion of the third metal layer ML3 is exposed by removing the first metal layer ML1 and the second metal layer ML2. The reflective opening OP can have a form surrounding the solder pattern 162 on a plane, and have a circular shape or quadrangular shape, but is not limited to.

The light emitted from the light-emitting element 10 is reflected from a surface of the third metal layer ML3 exposed by the reflective opening OP, which can have an effect of increasing the light efficiency of the display device.

The passivation layer 133 can be disposed on the first electrode 161 and the signal line TL and can include an opening hole 133a which exposes the solder pattern 162. Here, the opening hole 133a which exposes the solder pattern 162 can be referred to as a first opening hole. In this case, the reflective opening OP can be formed in a form surrounding the first opening hole.

The light-emitting element 10 can include a first conductivity-type semiconductor layer 10-1, an active layer 10-2 disposed on the first conductivity-type semiconductor layer 10-1, and a second conductivity-type semiconductor layer 10-3 disposed on the active layer 10-2. A first driving electrode 15 can be disposed under the first conductivity-type semiconductor layer 10-1, and a second driving electrode 14 can be disposed on the second conductivity-type semiconductor layer 10-3.

The light-emitting element 10 can be formed on a silicon wafer using a method such as metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), sputtering, or the like.

The first conductivity-type semiconductor layer 10-1 can be implemented with a compound semiconductor of group III-V, group II-VI, or the like and can be doped with a first dopant. The first conductivity-type semiconductor layer 10-1 can be formed of any one selected from semiconductor materials having a composition formula of Alₓ₁In_{y1}Ga_{(1-x1-y1)}N (0<=x1<=1, 0<=y1<=1, and 0<=x1+y1<=1), InAlGaN, AlGaAs, GaP, GaAs, GaAsP, and AlGaInP, but is not limited thereto. When the first dopant is an n-type dopant such as Si, Ge, Sn, Se, Te, or the like, the first conductivity-type semiconductor layer 10-1 can be an n-type nitride semiconductor layer. However, when the first dopant is a p-type dopant, the first conductivity-type semiconductor layer 10-1 can be a p-type nitride semiconductor layer.

The active layer 10-2 is a layer in which electrons (or holes) injected through the first conductivity-type semiconductor layer 10-1 and holes (or electrons) injected through the second conductivity-type semiconductor layer 10-3 meet. As the electrons and the holes recombine, the active layer 10-2 transitions to a lower energy level, and can generate light having a wavelength corresponding thereto.

The active layer 10-2 can have one structure among a single well structure, a multiple well structure, a single quantum well structure, a multi quantum well (MQW) structure, a quantum dot structure, and a quantum line structure, but the structure of the active layer 10-2 is not limited thereto. The active layer 10-2 can generate light in the visible light wavelength band. For example, the active layer 10-2 can output light in any one of the blue, green, and red wavelength bands.

The second conductivity-type semiconductor layer 10-3 can be disposed on the active layer 10-2. The second conductivity-type semiconductor layer 10-3 can be implemented with a compound semiconductor of group III-V, group II-VI, or the like, and can be doped with a second dopant. The second conductivity-type semiconductor layer 10-3 can be formed of any one selected from semiconductor materials having a composition formula of Inₓ₂Al_{y2}Ga_{1-x2-y2}N (0<=x2<=1, 0<=y2<=1, and 0<=x2+y2<=1), AlInN, AlGaAs, GaP, GaAs, GaAsP, and AlGaInP, but is not limited thereto. When the second dopant is a p-type dopant such as Mg, Zn, Ca, Sr, Ba, or the like, the second conductivity-type semiconductor layer 10-3 doped with the second dopant can be a p-type semiconductor layer. However, when the second dopant is an n-type dopant, the second conductivity-type semiconductor layer 10-3 can be an n-type nitride semiconductor layer.

In the embodiment, although a vertical structure in which the driving electrodes 14 and 15 are disposed at the top and bottom of a light-emitting structure is described, the light-emitting element can have a lateral structure or flip chip structure in addition to the vertical structure.

Referring to FIG. 7, a main light-emitting element 12a and a sub light-emitting element 12b of the sub-pixel can be disposed on the bank pattern 130. The second light-emitting element 12 will be described as an example. A 1-1 electrode 161-1 connected to the main light-emitting element 12a can extend along one side surface of the bank pattern 130 and can be electrically connected to a 2-1 connection line RT21 disposed at a lower portion. A 1-2 electrode 161-2 connected to the sub light-emitting element 12b can extend along the other side surface of the bank pattern 130 and can be electrically connected to a 2-2 connection line RT22 disposed at a lower portion.

The pixel driving circuit 20 can apply an anode voltage to the main light-emitting element 12a through the 2-1 connection line RT21, and apply an anode voltage to the sub light-emitting element 12b through the 2-2 connection line RT22. The pixel driving circuit 20 can apply a cathode voltage to the main light-emitting element 12a and the sub light-emitting element 12b through the first connection line RT1 and the second electrode 170.

The pixel driving circuit 20 can adjust luminance by driving only the main light-emitting element 12a, and can also adjust luminance by simultaneously driving the main light-emitting element 12a and the sub light-emitting element 12b. When the main light-emitting element 12a is darkened, luminance can be adjusted by driving only the sub light-emitting element 12b.

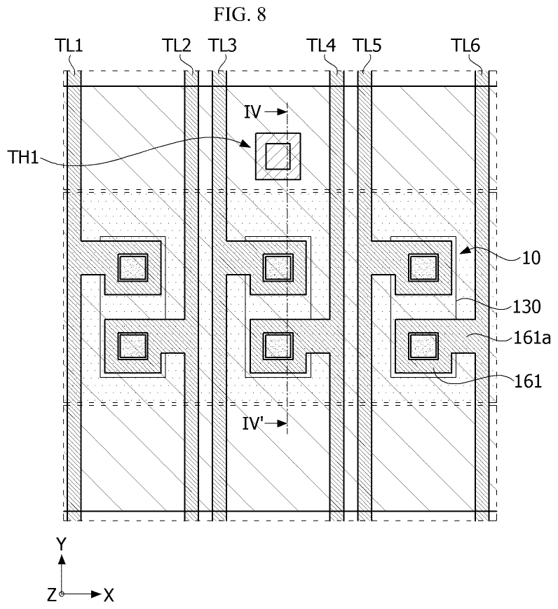

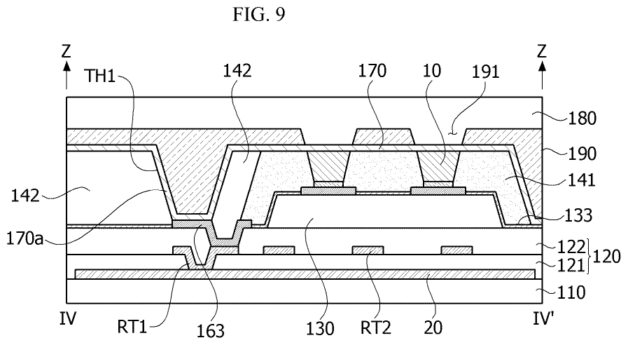

FIG. 8 is a view illustrating a display device according to another embodiment of the present disclosure. FIG. 9 is a cross-sectional view taken along line IV-IV′ in FIG. 8.

Referring to FIGS. 8 and 9, a second electrode 170 can be electrically connected to a contact electrode 163 through a contact hole TH1 formed in a second optical layer 142. The second optical layer 142 can include the contact hole TH1 which exposes the contact electrode 163. The second electrode 170 inserted into the contact hole TH1 of the second optical layer 142 can come into contact with an upper surface of the contact electrode 163. The contact hole TH1 can be formed in an outer region of a pixel.

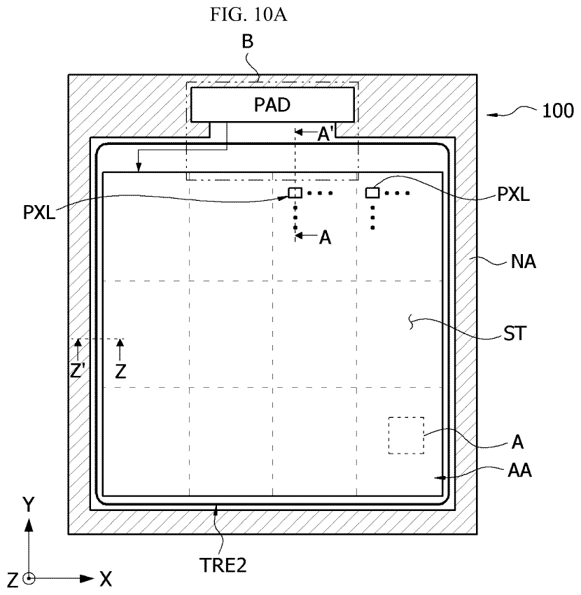

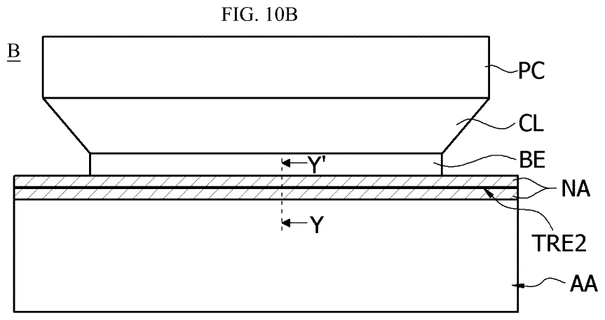

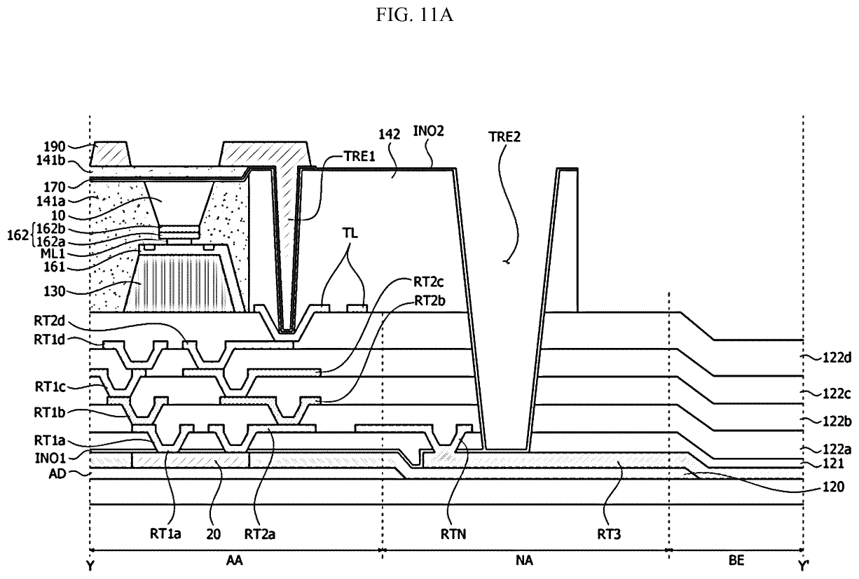

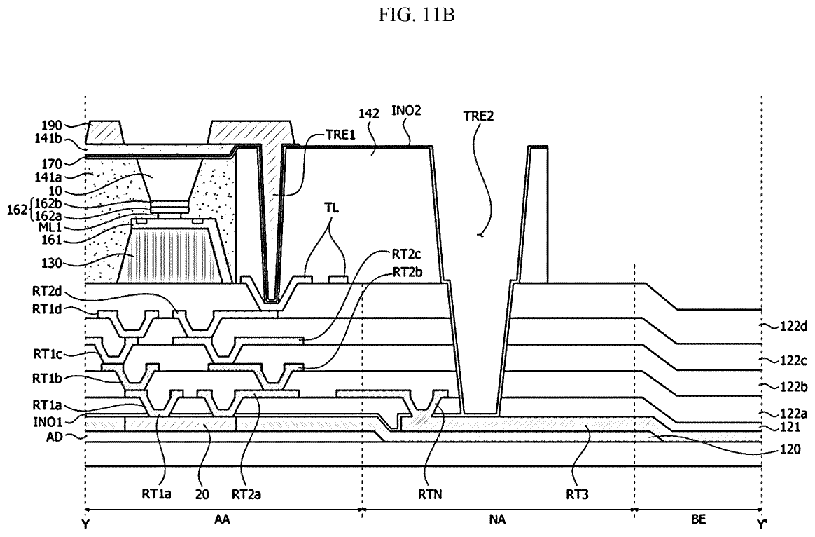

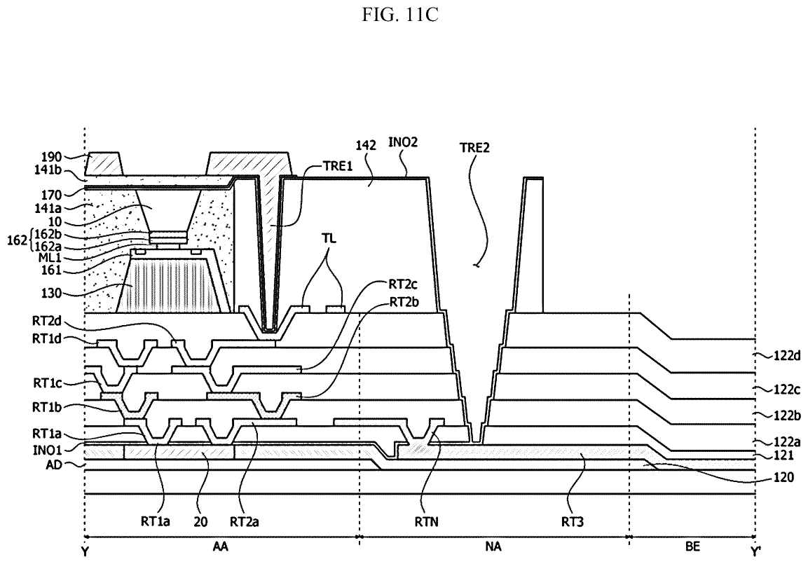

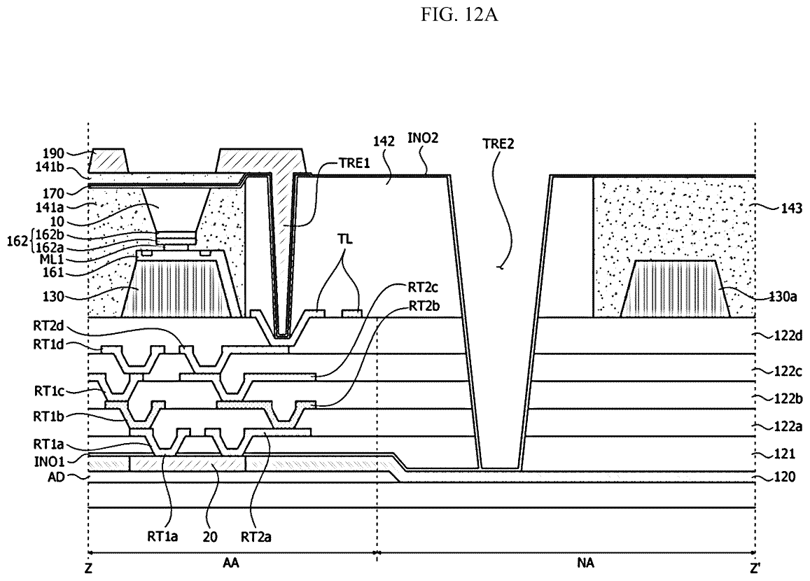

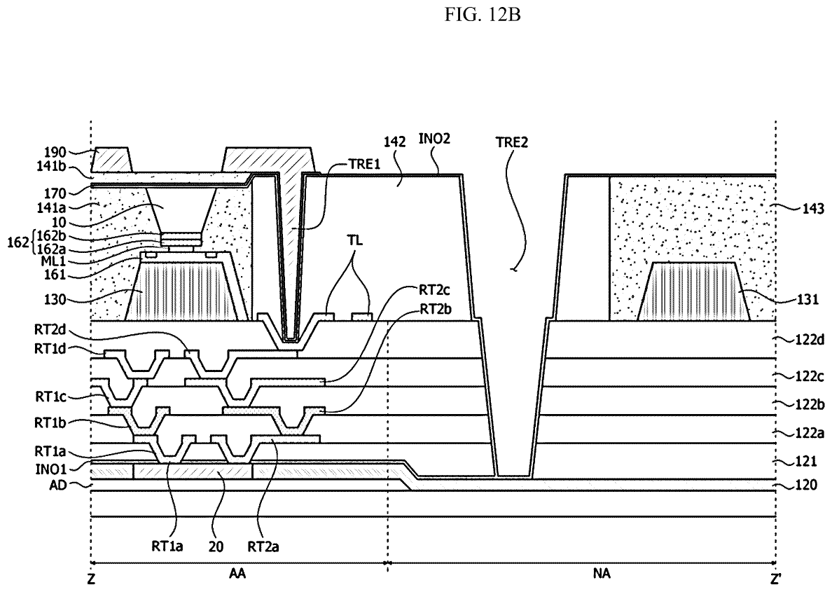

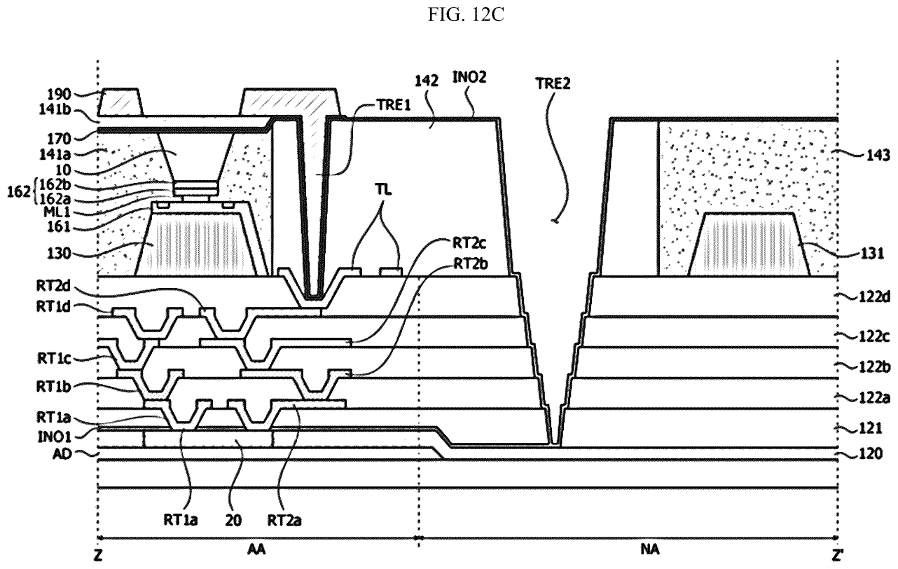

FIG. 10A is a view illustrating a display device according to another embodiment of the present disclosure. FIG. 10B is an enlarged view of region B in FIG. 10A. FIGS. 11A, 11B, and 11C are cross-sectional views taken along line Y-Y′ in FIG. 10B. FIGS. 12A, 12B, and 12C are cross-sectional views taken along line Z-Z′ in FIG. 10A.

Hereinafter, since the content for configurations such as the configurations included in the embodiment described in FIGS. 1 to 9 is redundant and will be omitted, the description will focus on other features.

Referring to FIGS. 10A and 10B, a display panel can include a display region AA where an image is displayed and a non-display region NA where the image is not displayed. In the non-display region NA, various lines and driving circuits can be mounted, and a pad portion PC to which an integrated circuit, a printed circuit, and the like are connected can be disposed. A bending region BE can be disposed between the non-display region NA and the pad portion PC, and a connection line region CL can be disposed between the bending region BE and the pad portion PC.

In the non-display region NA, data driving circuits or gate driving circuits can be disposed, and lines supplying control signals for controlling these driving circuits can be disposed. Here, the control signals can include various timing signals including clock signals, input data enable signals, and synchronization signals and can be received from the pad portion PC through lines disposed in the connection line region CL.

A protective pattern TRE2 can be formed in the non-display region NA to surround the display region AA. An outer bank pattern 130a disposed to surround the protective pattern TRE2 and an outer optical layer 143 disposed to cover the outer bank pattern 130a can be disposed in the non-display region NA.

The pad portion PC can include a first region (film on panel, FP) to which a chip on film (COF) is attached. As will be described below, a partial insulating layer in the first region FP can be removed.

Circuit components can be disposed directly on the pad portion PC or attached to the pad portion PC in the form of a chip on panel (COP) or COF.

The circuit components can include a printed circuit board (PCB). The chip on film (COF) can process various signals input from the printed circuit board (PCB) and output the signals to the display panel. To this end, one end of the chip on film (COF) can be attached to the display panel, and the other end opposite the one end can be attached to the printed circuit board (PCB).

Various driving circuits, such as a timing controller and the like can be mounted on the printed circuit board (PCB), and various signals generated from the driving circuits can be output to the chip on film (COF). The printed circuit board (PCB) can include, for example, a flexible printed circuit board (FPCB).

The display panel and the chip on film (COF) overlapping at least a portion of the display panel can be adhered to each other by an anisotropic conductive film (ACF) disposed therebetween.

Referring to another embodiment of the present disclosure shown in FIGS. 11A and 12A, the display device according to another embodiment includes a plurality of first electrodes 161 and a contact electrode 163 disposed on a substrate 110, a plurality of light-emitting elements 10 disposed on the plurality of first electrodes 161, a first optical layer 141 disposed between the plurality of light-emitting elements 10, and a second electrode 170 disposed on the plurality of light-emitting elements 10.

An adhesive layer AD can be disposed on the substrate 110. A region where the adhesive layer AD is removed can be present in the non-display region NA or bending region BE. This is because the more organic layers there are in the bending region BE, the higher the risk of an organic layer being damaged or broken in the bending region BE. The adhesive layer AD can be selected from, for example, any one of an adhesive polymer, an epoxy resin, an ultraviolet (UV) resin, the polyimide series, the acrylate series, the urethane series, and a polydimethylsiloxane (PDMS), but is not limited thereto.

A pixel driving circuit 20 implemented as a driving driver can be disposed on the adhesive layer AD in the display region AA.

A protective layer 120 can be formed on the adhesive layer AD to protect the pixel driving circuit 20. The protective layer 120 can cover at least a portion or all of a side surface of the pixel driving circuit 20 and cover a portion of an upper surface of the pixel driving circuit 20. The protective layer 120 can cover all of the substrate 110 and cover a portion or all of the pad portion PC. The protective layer 120 can be made of an organic insulating material, for example, photosensitive photo acryl or photosensitive polyimide, but is not limited thereto.

A buffer layer 121 which covers the pixel driving circuit 20 can be disposed on the protective layer 120.

A first inorganic film INO1 can be disposed on the protective layer 120. The first inorganic film INO1 can be formed as a single layer or multiple layers of an inorganic material such as SiNₓ and/or SiOₓ. When the protective layer 120 is made of an organic material, since penetration of moisture, hydrogen, or the like may not be prevented, defects such as corrosion or the like of metal lines can occur, which can affect the normal operation of the pixel driving circuit 20. Since the first inorganic film INO1 is made of an inorganic material and thus is resistant to external moisture penetration, the defects caused by moisture or the like can be prevented from occurring.

A third connection line RT3 can be disposed on the protective layer 120.

An insulating layer 122 can be disposed on the buffer layer 121. An intermediate connection line RTN connected to a 1a connection line RT1a, a 2a connection line RT2a, and the third connection line RT3 can be disposed on the buffer layer 121.

A first insulating layer 122a which covers the 1a connection line RT1a, the 2a connection line RT2a, and the intermediate connection line RTN can be disposed on the buffer layer 121.

A 1b connection line RT1b and a 2b connection line RT2b can be disposed on the first insulating layer 122a.

A second insulating layer 122b which covers the 1b connection line RT1b and the 2b connection line RT2b can be disposed on the first insulating layer 122a.

A 1c connection line RT1c and a 2c connection line RT2c can be disposed on the second insulating layer 122b.

A third insulating layer 122c which covers the 1c connection line RT1c and the 2c connection line RT2c can be disposed on the second insulating layer 122b.

A 1d connection line RT1d and a 2d connection line RT2d can be disposed on the third insulating layer 122c.

A fourth insulating layer 122d which covers the 1d connection line RT1d and the 2d connection line RT2d can be disposed on the third insulating layer 122c. The more insulating layers there are in the bending region BE, the more likely it is that the insulating layer will be damaged during bending. The fourth insulating layer 122d may not be disposed in the bending region BE, the non-display region NA adjacent to the bending region BE, and the connection line region CL. N insulating layers (0<N<5 and N is an integer) can be disposed in the bending region BE.

A plurality of signal lines TL, a contact electrode, and a seventh signal line can be disposed on the fourth insulating layer 122d. For example, the plurality of signal lines TL, the contact electrode, and the seventh signal line can be disposed on the same layer. Being disposed on the same layer can mean being entirely formed on one layer and then spaced apart through a patterning process or the like. However, the present disclosure is not necessarily limited thereto and heights can be different, but if a plurality of lines or electrodes are formed on the same layer, the plurality of lines or electrodes can be defined as being disposed on the same layer.

The 1a connection line RT1a, the 1b connection line RT1b, the 1c connection line RT1c, the 1d connection line RT1d, and the plurality of signal lines TL can be electrically connected through contact holes passing through insulating layers and inorganic films where the 1a connection line RT1a, the 1b connection line RT1b, the 1c connection line RT1c, the 1d connection line RT1d, and the plurality of signal lines TL are respectively disposed.

The 2a connection line RT2a, the 2b connection line RT2b, the 2c connection line RT2c, the 2d connection line RT2d, and the contact electrode 163 can be electrically connected through contact holes passing through insulating layers and inorganic films where the 2a connection line RT2a, the 2b connection line RT2b, the 2c connection line RT2c, the 2d connection line RT2d, and the contact electrode 163 are respectively disposed.

An anode voltage supplied from the pixel driving circuit 20 can be supplied to the light-emitting element 10 through the 1a connection line RT1a, the 1b connection line RT1b, the 1c connection line RT1c, the 1d connection line RT1d, the plurality of signal lines TL, and the first electrode 161.

A cathode voltage supplied from the pixel driving circuit 20 can be supplied to the light-emitting element 10 through the 2a connection line RT2a, the 2b connection line RT2b, the 2c connection line RT2c, the 2d connection line RT2d, the plurality of signal lines TL, and the first electrode 161.

The connection lines listed above are examples, and each connection line can include a plurality of line patterns disposed on different layers with one or more insulating layers interposed therebetween. The line patterns disposed on different layers can be electrically connected through contact holes passing through the insulating layers.

The third connection line RT3 is disposed on the protective layer 120. The third connection line RT3 can extend from the display region AA to the pad portion PC.

A fourth connection line can be disposed on the first insulating layer 122a and extend to the pad portion PC and the connection line region CL.

A fifth connection line can be disposed on the second insulating layer 122b and extend to the pad portion PC and the connection line region CL.

A sixth connection line can be disposed on the third insulating layer 122c and extend to the pad portion PC and the connection line region CL.

A seventh connection line can be disposed on the fourth insulating layer 122d and extend to the pad portion PC and the connection line region CL.

Signals output from a circuit component such as a printed circuit board (PCB) can be transmitted to the pixel driving circuit 20 disposed in the display region AA through the chip on film (COF), the seventh connection line, the sixth connection line, the fifth connection line, the fourth connection line, and the third connection line RT3.

A plurality of bank patterns 130 can be disposed on the insulating layer 122. At least one light-emitting element 10 can be disposed on each bank pattern 130. For example, referring to FIGS. 3, 11A, and 12A, a first light-emitting element 11 can be disposed on a first bank pattern 130a, a second light-emitting element 12 can be disposed on a second bank pattern 130b, and a third light-emitting element 13 can be disposed on a third bank pattern 130c.

The first electrode 161 can be disposed on the bank pattern 130. In the embodiment, the first electrode 161 can include a plurality of metal layers ML2, ML3, and ML4 except for a first metal layer ML1 during a formation process, and in a separate process, the first metal layer ML1 can be disposed only in a region overlapping the first electrode 161 and the light-emitting element 10. An opening OP can be disposed in the first electrode 161. In the embodiment, the opening OP can be formed by removing the second metal layer ML2. The first metal layer ML1 may not be disposed on the pad portion PC. Further, the first metal layer ML1 may not be disposed in regions other than the region overlapping the light-emitting element 10.

A solder pattern 162 can be disposed on the first electrode 161. The solder pattern 162 can be made of indium (In), tin (Sn), or an alloy thereof, but is not limited thereto. The solder pattern 162 can include a first portion 162a and a second portion 162b. The first portion 162a can include indium (In), and the second portion 162b can include gold (Au). When the light-emitting element 10 is transferred, the first portion 162a and the second portion 162b can be bonded by pressure and then cutectically bonded by applying heat. When the second portion 162b receives pressure, a portion of the second portion 162b can cover at least a portion or all of a side surface of the first portion 162a. In this case, since a contact area between the first portion 162a and the second portion 162b increases, adhesion can increase and electrical signal transmission can be improved.

The plurality of light-emitting elements 10 can each be mounted on the solder pattern 162.

A 1-1 optical layer 141a can cover the plurality of light-emitting elements 10 and the bank patterns 130. Accordingly, the 1-1 optical layer 141a can cover a space between the plurality of light-emitting elements 10 and a space between the plurality of bank patterns 130. Disposition of the 1-1 optical layer 141a on a plane is the same as disposition of the first optical layer 141 on a plane.

The second electrode 170 can be disposed on the plurality of light-emitting elements 10. The second electrode 170 can be connected to the plurality of pixels PXL in common.

A second protective pattern TRE2 can be formed in the non-display region NA to surround the display region AA. The second protective pattern TRE2 can be formed by disposing a 1-2 optical layer 141b and then removing the first to fourth insulating layers 122a, 122b, 122c, 122d and the second optical layer 142. An outer bank pattern 130a disposed to surround the second protective pattern TRE2 and an outer optical layer 143 disposed to cover the outer bank pattern 130a can be disposed in the non-display region NA. The outer bank pattern 130a and the outer optical layer 143 can be formed on three sides of the four sides surrounding the display panel except for the side adjacent to the bending region BE. The outer bank pattern 130a can be formed of the same material in the same process as the bank pattern 130. The outer optical layer 143 can be formed of the same material in the same process as the 1-1 optical layer 141a.

After forming a first protective pattern TRE1 and the second protective pattern TRE2, a second inorganic film INO2 can be disposed to cover the display region AA and the non-display region NA. The second inorganic film INO2 can completely cover the inside of the first protective pattern TRE1 and the second protective pattern TRE2, and a portion of the second inorganic film INO2 can be in contact with the first inorganic film INO1 in the second protective pattern TRE2. Further, the second protective pattern TRE2 can be disposed between the second electrode 170 and the 1-2 optical layer 141b in a region adjacent to the light-emitting element 10 in the process sequence. The second protective pattern TRE2 can completely cover the outer optical layer 143, but can also cover only a portion of the outer optical layer 143 in the non-display region NA. The second inorganic film INO2 can be formed of the same material as the first inorganic film INO1, but is not limited thereto.

As described above, when the first protective pattern TRE1, the second protective pattern TRE2, the first inorganic film INO1, and the second inorganic film INO2 are disposed, since the entry of foreign substances such as moisture, hydrogen, and the like which penetrate from the outside is prevented or delayed, a defect such as corrosion or damage to the metal line and the like in the display panel can be prevented. Further, as the outer optical layer 143 and the outer bank pattern 130a are disposed, thicknesses of the second optical layer 142 and the second inorganic film INO2 disposed in the non-display region NA can have values the same as or similar to a thickness of that in the display region AA, and a defect in which organic layers such as the second optical layer 142 and the like flow out of the non-display region NA of the display panel due to process problems can be prevented.

The 1-2 optical layer 141b can be disposed to overlap the 1-1 optical layer 141a on the second electrode 170. The 1-2 optical layer 141b can be disposed on the second electrode 170 to increase the amount of light emitted to the front.

After forming the 1-1 optical layer 141a, the 1-1 optical layer 141a located in a region adjacent to an upper surface of the light-emitting element 10 is removed to bring the second electrode 170 and the light-emitting element 10 into contact with each other. Thereafter, the second electrode 170 is disposed on the 1-1 optical layer 141a. Further, the 1-1 optical layer 141a or 1-2 optical layer 141b is removed and the first protective pattern TRE1 is formed to supply a cathode voltage to the second electrode 170. The second electrode 170 can be electrically connected to the signal line TL formed on the fourth insulating layer 122d through the first protective pattern TRE1 and receive the cathode voltage.

The second optical layer 142 can be an organic insulating material surrounding the first optical layer 141. The second optical layer 142 can be disposed on the insulating layer 122 along with the first optical layer 141. The 1-1 optical layer 141a and the 1-2 optical layer 141b can be disposed in the display region AA, but the second optical layer 142 can be disposed in the display region AA and the non-display region NA. A black matrix 190 can be disposed on the 1-2 optical layer 141b. The black matrix 190 can be disposed on the 1-2 optical layer 141b, the second inorganic film INO2, and the second optical layer 142. Transmission holes 191 through which light emitted from the light-emitting elements 10 is emitted to the outside can be formed between the patterns of the black matrix 190.

A cover layer 180 can be an organic insulating material which covers the black matrix 190 and the second inorganic film 141b.

In order to protect the plurality of connection lines RT1a, RT1b, RT1c, RT1d, RT2a, RT2b, RT2c, and RT2d disposed in the display region AA from foreign substances such as moisture and the like, an inorganic film can be further disposed to cover each of the connection lines after forming the connection lines. For example, after forming the 1a connection line RT1a and the 2a connection line RT2a, an inorganic film which covers the 1a connection line RT1a, the 2a connection line RT2a, and the buffer layer 121 can be further disposed.

According to one embodiment of the present disclosure according to FIG. 11A, the third connection line RT3 can transmit electrical signals received from the pad portion to the pixel driving circuit 20 through the intermediate connection line RTN, the 1a connection line RT1a, and the 2a connection line RT2a.

The intermediate connection line RTN can be formed of the same material in the same process as the 1a connection line RT1a and the 2a connection line RT2a.

The second protective pattern TRE2 is formed so that an upper portion of the third connection line RT3 is exposed, and then can be covered by the second inorganic film INO2.

The third connection line RT3 can be in direct contact with a portion of the first inorganic film INO1 and at least a portion of the second inorganic film INO2.

According to one embodiment of the present disclosure according to FIGS. 11A and 12A, the second protective pattern TRE2 can be formed to have the same taper without flat portions at boundaries between the buffer layer 121, the plurality of insulating layers 122a, 122b, 122c, and 122d, and the second optical layer 142.

According to another embodiment of the present disclosure according to FIGS. 11B and 12B, when the second protective pattern TRE2 is formed, the plurality of insulating layers 122a, 122b, 122c, and 122d and the second optical layer 142 can be removed in separate processes according to the process environment and equipment. For example, the second protective pattern TRE2 can be formed by first removing the plurality of insulating layers 122a, 122b, 122c, and 122d in a region where the second protective pattern TRE2 will be formed after disposing the fourth insulating layer 122d is disposed, and then disposing and removing the second optical layer 142. Accordingly, a region having a flat surface can be formed at the boundary between the uppermost surface of the plurality of insulating layers 122a, 122b, 122c, and 122d and the second optical layer 142, and an inclination angle (taper) of the second inorganic film INO2 disposed on inclined surfaces of the plurality of insulating layers 122a, 122b, 122c, and 122d and an inclination angle of the second inorganic film INO2 disposed on an inclined surface of the second optical layer 142 can be different.

According to still another embodiment of the present disclosure according to FIGS. 11C and 12C, when the second protective pattern TRE2 is formed, each insulating layer included in the plurality of insulating layers 122a, 122b, 122c, and 122d and the second optical layer 142 can be removed in a separate process for each layer according to the process environment and equipment. Accordingly, a region having a flat surface can be formed at boundaries between the plurality of insulating layers 122a, 122b, 122c, and 122d and a boundary between the fourth insulating layer 122d and the second optical layer 142, and inclination angles (taper) of the second inorganic film INO2 disposed on inclined surfaces of the plurality of insulating layers 122a, 122b, 122c, and 122d and an inclined surface of the second optical layer 142 can be different from each other.

In the embodiment, although a vertical structure in which driving electrodes 14 and 15 are disposed at the top and bottom of the light-emitting structure is described, the light-emitting element can have a lateral structure or flip chip structure in addition to the vertical structure.

The display device according to the embodiments of the present disclosure can be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an electronic book, a portable multimedia player (PMP), a personal digital assistant (PDA), an MP3 player, a mobile medical apparatus, a desktop personal computer (PC), a laptop PC, a netbook computer, a workstation, a navigation device, a vehicle display device, a theater display device, a television, a wallpaper apparatus, a signage apparatus, a game device, a notebook, a monitor, a camera, a camcorder, a home appliance, and the like. Further, the display device according to one or more embodiments of the present disclosure can be applied to an inorganic light-emitting lighting device.

The display device according to one or more embodiments of the present disclosure can be described as follows.

A display device according to one or more embodiments of the present disclosure includes a substrate including a display region, a non-display region, and a bending region; an adhesive layer disposed on the substrate; a pixel driving circuit disposed on the adhesive layer in the display region; a buffer layer disposed on the adhesive layer and configured to cover the pixel driving circuit; a second protective pattern disposed in the non-display region to surround the display region; a first inorganic film disposed on the pixel driving circuit; and a second inorganic film disposed on the second protective pattern in the display region and the non-display region, wherein the first inorganic film and the second inorganic film overlap in a region overlapping the second protective pattern.

The first inorganic film can extend only to a region overlapping the second protective pattern.

Further, the display device according to one or more embodiments of the present disclosure can further include a protective layer disposed on the adhesive layer and under the first inorganic film, and covering at least a portion or all of a side surface of the pixel driving circuit; a plurality of insulating layers disposed on the buffer layer; a bank pattern disposed on the plurality of insulating layers; a plurality of light-emitting elements disposed on the bank pattern; a 1-1 optical layer disposed on the insulating layer and configured to cover the plurality of light-emitting elements and the bank pattern; and a second optical layer disposed on the same layer as the 1-1 optical layer to surround a side surface of the 1-1 optical layer.

In addition, the display device according to one or more embodiments of the present disclosure can further include an outer bank pattern formed on the same layer as the bank pattern and disposed to surround the protective pattern; and an outer third optical layer disposed to cover the outer bank pattern, and the second inorganic film can be disposed on the outer optical layer, and the outer bank pattern can be disposed further away from the display region than the second protective pattern.

In addition, the display device according to one or more embodiments of the present disclosure can further include a plurality of connection lines respectively disposed on the plurality of insulating layers; and a third connection line disposed on the protective layer to extend from the bending region to the display region, and a surface of the third connection line can overlap the first inorganic film and the second inorganic film in a region overlapping the second protective pattern.

The second protective pattern can be formed by removing the plurality of insulating layers and the second optical layer.

The second inorganic film disposed on an inclined surface of the second protective pattern can have the same angle.

The second inorganic film disposed on an inclined surface of the second protective pattern can have a flat surface on the uppermost surface of the plurality of insulating layers.

The second inorganic film disposed on an inclined surface of the second protective pattern can have a flat surface on an upper surface of each of the plurality of insulating layers.

Further, the display device according to one or more embodiments of the present disclosure can further include a first electrode disposed on the bank pattern; a first metal layer disposed on the first electrode; a solder pattern disposed on the first metal layer; and a second electrode disposed on the light-emitting element, and the light-emitting element can be disposed on the solder pattern.

Further, the display device according to one or more embodiments of the present disclosure can further include a 1-2 optical layer disposed on the second electrode and overlapped with the 1-1 optical layer; and a first protection layer on the plurality of insulating layers and formed by removing at least one of the 1-1 optical layer and the 1-2 optical layer.

A region where the adhesive layer is removed can be present in at least one of the non-display region and the bending region.

The outer bank pattern can be formed of the same material as the bank pattern, and the outer optical layer can be formed of the same material as the 1-1 optical layer.

According to aspects of the present disclosure, as a first protective pattern, a second protective pattern, a first inorganic film, and a second inorganic film are disposed to prevent or delay the entry of foreign substances such as moisture, hydrogen, and the like which penetrate from the outside, a defect such as corrosion or damage to a metal line and the like in a display panel can be prevented. Further, as an outer optical layer and an outer bank pattern are disposed, thicknesses of a second optical layer and the second inorganic film disposed in a non-display region can have values the same as or similar to a thickness of that in the display region, and a defect in which organic layers such as the second optical layer and the like flow out of the non-display region of the display panel due to process problems can be prevented.

The various and helpful advantages and effects of the present disclosure are not limited to the above-described content, and other effects which are not mentioned will be clearly understood by those skilled in the art from the description above.

Since the problems to be solved, the means to solve the problem, and the effects described above described in the content of the disclosure does not specify the essential features of the claims, the scope of the claims is not limited by the items described in the content of the disclosure.

Although the embodiments of the present disclosure have been described in more detail with reference to the accompanying drawings, the present disclosure is not necessarily limited to these embodiments, and can be variously modified without departing from the technical spirit of the present disclosure. Accordingly, the embodiments disclosed in the present disclosure are not intended to limit the technical spirit of the present disclosure, but to describe the technical spirit of the present disclosure, and the scope of the technical spirit of the present disclosure is not limited by these embodiments. Accordingly, the above-described embodiments should be understood in all respects as illustrative and not restrictive.

What is claimed is:

1. A display device comprising:
a substrate including a display region, a non-display region, and a bending region;
an adhesive layer disposed on the substrate;
a pixel driving circuit disposed on the adhesive layer in the display region;
a buffer layer disposed on the adhesive layer and configured to cover the pixel driving circuit;
a second protective pattern disposed in the non-display region to surround the display region;
a first inorganic film disposed on the pixel driving circuit; and
a second inorganic film disposed on the second protective pattern in the display region and the non-display region,
wherein the first inorganic film and the second inorganic film overlap in a region overlapping the second protective pattern.

2. The display device of claim 1, wherein the first inorganic film extends only to the region overlapping the second protective pattern.

3. The display device of claim 1, further comprising:
a protective layer disposed on the adhesive layer and under the first inorganic film, and covering at least a portion or all of a side surface of the pixel driving circuit;
a plurality of insulating layers disposed on the buffer layer;
a bank pattern disposed on the plurality of insulating layers;
a plurality of light-emitting elements disposed on the bank pattern;
a 1-1 optical layer disposed on at least one of the plurality of insulating layers and configured to cover the plurality of light-emitting elements and the bank pattern; and
a second optical layer disposed on a same layer as the 1-1 optical layer to surround a side surface of the 1-1 optical layer.

4. The display device of claim 3, further comprising:
an outer bank pattern disposed on a same layer as the bank pattern, and disposed to surround the protective pattern; and
an outer optical layer disposed to cover the outer bank pattern,
wherein the second inorganic film is disposed on the outer optical layer, and
wherein the outer bank pattern is disposed further away from the display region than the second protective pattern.

5. The display device of claim 4, further comprising:
a plurality of connection lines respectively disposed on the plurality of insulating layers; and
a third connection line disposed on the protective layer to extend from the bending region to the display region,
wherein a surface of the third connection line overlaps the first inorganic film and the second inorganic film in the region overlapping the second protective pattern.

6. The display device of claim 5, wherein the second protective pattern is formed by removing the plurality of insulating layers and the second optical layer.

7. The display device of claim 6, wherein the second inorganic film disposed on an inclined surface of the second protective pattern has a same angle.

8. The display device of claim 6, wherein the second inorganic film disposed on an inclined surface of the second protective pattern has a flat surface on an uppermost surface of the plurality of insulating layers.

9. The display device of claim 6, wherein the second inorganic film disposed on an inclined surface of the second protective pattern has a flat surface on an upper surface of each of the plurality of insulating layers.

10. The display device of claim 7, further comprising:
a first electrode disposed on the bank pattern;
a first metal layer disposed on the first electrode;
a solder pattern disposed on the first metal layer; and
a second electrode disposed on one of the plurality of light-emitting elements,
wherein the one of the plurality of light-emitting elements is disposed on the solder pattern.

11. The display device of claim 10, further comprising:
a 1-2 optical layer disposed on the second electrode and overlapped with the 1-1 optical layer; and
a first protection layer on the plurality of insulating layers and formed by removing at least one of the 1-1 optical layer and the 1-2 optical layer.

12. The display device of claim 1, wherein a region where the adhesive layer is removed is present in at least one of the non-display region and the bending region.

13. The display device of claim 4, wherein the outer bank pattern includes a same material as the bank pattern, and the outer optical layer includes a same material as the 1-1 optical layer.
